(19) United States
(12) Patent Application Publication
(10) Pub. No.: US 2006/0286693 A1
(43) Pub. Date: Dec. 21, 2006

(54) FABRICATION OF THREE-DIMENSIONAL PHOTONIC CRYSTALS IN GALLIUM ARSENIDE-BASED MATERIAL

(75) Inventors: Janusz Murakowski, Newark, DE (US); Christopher A. Schuetz, Newark, DE (US); Dennis W. Prather, Newark, DE (US)

Correspondence Address: CONNOLLY BOVE LODGE & HUTZ LLP, P.O. BOX 2207, WILMINGTON, DE, 19899-2207, US

(73) Assignee: University of Delaware, Newark, DE (US)

(21) Appl. No.: 11/424,362

(22) Filed: Jun. 15, 2006

Related U.S. Application Data
(60) Provisional application No. 60/690,504, filed on Jun. 15, 2005.

(51) Int. Cl. H01L 21/00

(52) U.S. Cl. 438/22

(57) ABSTRACT

The present invention is an efficient method for the fabrication of three-dimensional structures in GaAs-based materials. The method is particularly suitable for the realization of 3D photonic crystals. The method relies on the observation that the oxidation rate of Ga₁₋ₓA1ₓAs in water-vapor atmosphere is a strong function of the aluminum content in the alloy. Thus, a stack of Ga₁₋ₓA1ₓAs layers with varying concentration of A1 is grown on GaAs substrate. The top surface is patterned with an array of holes, which are then transferred to the underlying layers by dry etching. Subjecting the so-prepared structure to oxidation in water vapor atmosphere at an elevated temperature results in lateral oxidation of the material exposed by the etched holes. The lateral oxidation depth depends on aluminum content in a particular layer. The oxide is then removed by an aqueous solution of hydrofluoric acid and a three-dimensional array of voids ensues. The shape of the voids depends on the variation of aluminum content in the layers of the stack. Depending on the 2D pattern on top surface of the structure, various arrays of voids can be realized.

### BACKGROUND OF THE INVENTION

Background art methods for fabricating three-dimensional (3D) photonic crystals often require building a structure layer by layer. With these background art methods, consecutive layers have to be precisely aligned in order to achieve a functional structure. The requirement of such an alignment results in a process that is both labor-intensive and difficult to control. Therefore, there is a need in the art for simpler methods for fabricating 3D structures in the form of photonic crystals.

### SUMMARY OF THE INVENTION

The present invention is a method for fabricating three-dimensional structures. The method can be advantageously applied to fabricating such structures in the form of photonic crystals. The primary elements of the method are: (1) growing a plurality of layers with variable composition on a substrate; (2) vertically etching through the plurality of layers; and (3) creating a chemical reaction having a composition-dependent rate to selectively remove the variable composition material to different depths in order to form a three-dimensional structure.

In particular, one embodiment of the present invention is a method for fabricating three-dimensional structures comprising: preparing a GaAs substrate; growing a plurality of layers of AlₓGa₁₋ₓAs, wherein at least two of the plurality of layers differ in A1 content (i.e., “x” parameter), on top the GaAs substrate; patterning and etching an array of holes through the plurality of layers; oxidizing the plurality of layers; and selectively etching oxidized regions of the plurality of layers to fabricate three dimensional structures.

Regarding the embodiment of the present invention discussed above, preferably, removing surface contaminants and native oxide is performed by using at least one of organic and inorganic solvents. Preferably, the plurality of layers further comprises layers of Ga₁₋ₓA1ₓAs, wherein at least two of the plurality of layers differ in A1 content. Preferably, a concentration of A1 and Ga are varied in accordance with a value for x. Preferably, transferring the array of holes further comprises using a chlorine-based dry etch. Preferably, oxidizing the plurality of layers is performed in a temperature range of 300° C. and 600° C. Preferably, oxidizing the plurality of layers is performed in an atmosphere containing water. Preferably, oxidizing the plurality of layers is performed in an atmosphere of water vapor and nitrogen. Preferably, selective etching of the oxidized plurality of layers is performed by using an aqueous solution of hydrofluoric acid.

Another embodiment of the present invention is a method for fabricating three-dimensional structures comprising: preparing a substrate; growing a plurality of layers on top of the substrate where at least two of the plurality of layers differ in chemical composition; patterning the top surface of the plurality of layers with a plurality of holes; transferring the plurality of holes to the plurality of layers by etching; exposing the plurality of layers to a fluid chemical agent where a reaction rate of a fluid chemical agent is dependent on a chemical composition o the plurality of layers; and thereby creating a three-dimensional structure of varied chemical composition.

Regarding the embodiment of the present invention discussed above, preferably, the plurality of layers comprises at least one layer of Ga₁₋ₓA1ₓAs. Preferably the fluid chemical agent comprises water vapor to oxidize Ga₁₋ₓA1ₓAs. Preferably, the oxidized Ga₁₋ₓA1ₓAs is subsequently selectively removed. Preferably, an aqueous solution of hydrofluoric acid is used to remove said oxidized Ga₁₋ₓA1ₓAs.

### BRIEF DESCRIPTION OF THE DRAWINGS

The invention can be described in greater detail with the aid of the following drawings.

FIG. 1(a) shows a GaAs substrate.

FIG. 1(b) shows a plurality of layers of Ga₁₋ₓA1ₓAs grown on top of the GaAs substrate.

FIG. 1(c) shows patterning and etching an array of holes in the plurality of layers of AlₓGa₁₋ₓAs grown on top of the GaAs substrate.

FIG. 1(d) shows oxidation of the plurality of layers of A1ₓGa₁₋ₓAs grown on top of the GaAs substrate.

FIG. 1(e) shows selectively etching of the oxidized portions of the plurality of layers grown on top of the GaAs substrate to produce a three-dimensional structure.

FIG. 2 is a flow diagram of the process steps for fabricating a three-dimensional structure.

### DETAILED DESCRIPTION OF THE PREFERRED EMBODIMENT

The present invention is a fabrication process for realizing three-dimensional structures, such as photonic crystals, in the bulk of mono-crystalline III-V semiconductor substrates. The process relies on the dependence of the oxidation rate on the specific composition of the semiconductor, and subsequent selective etching that attacks only the oxidized portion of the semiconductor.

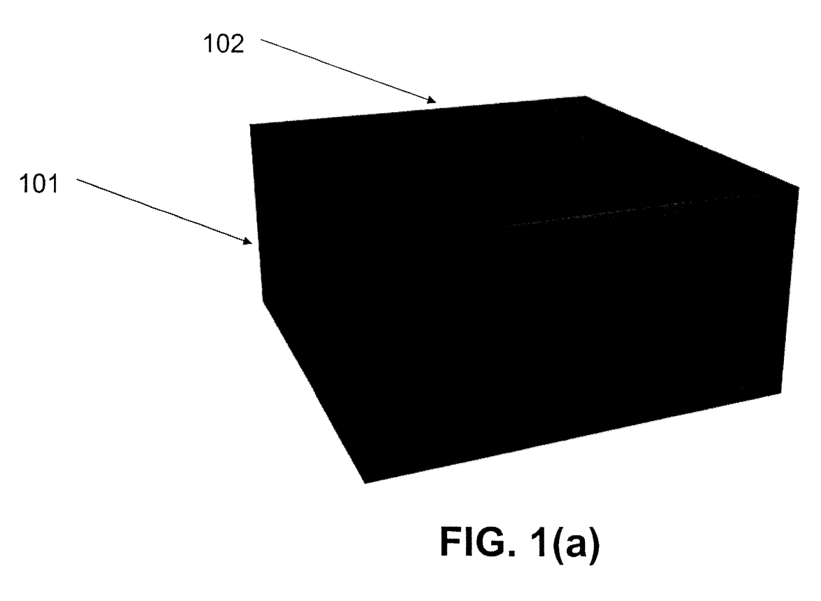

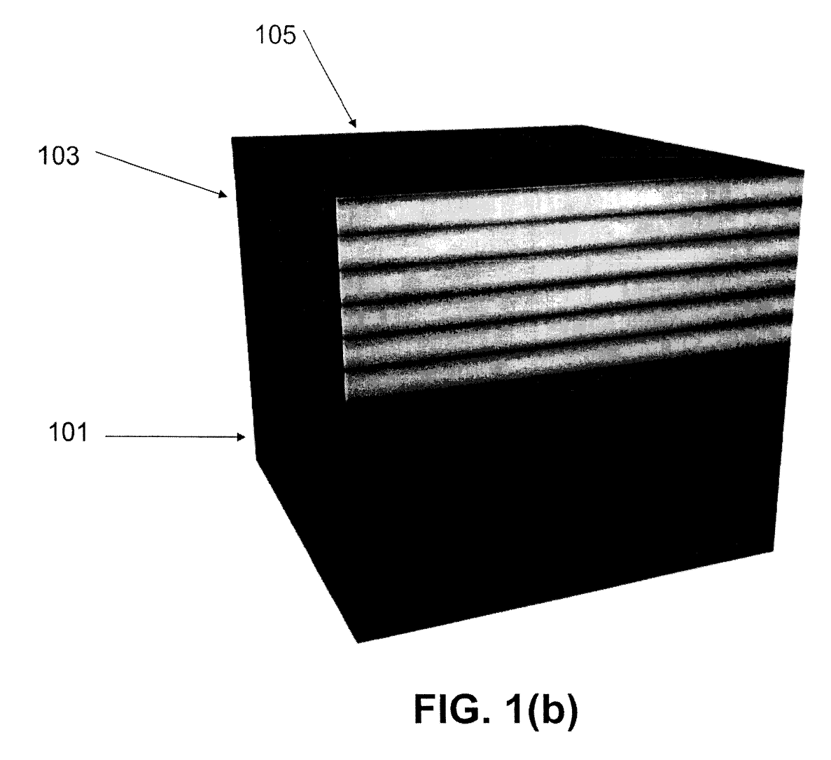

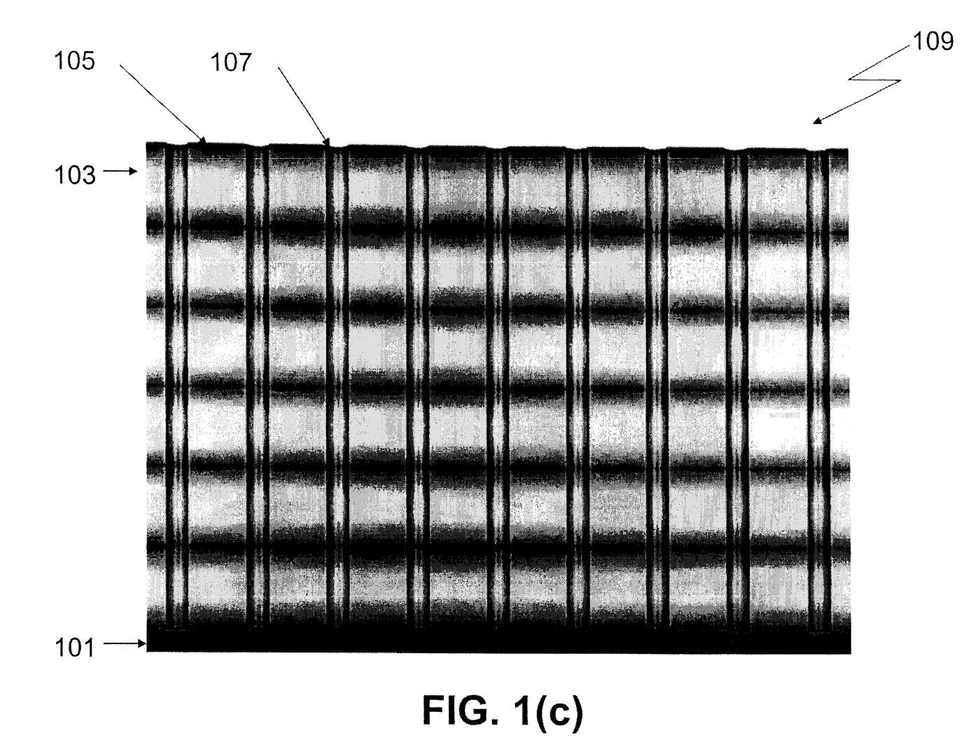

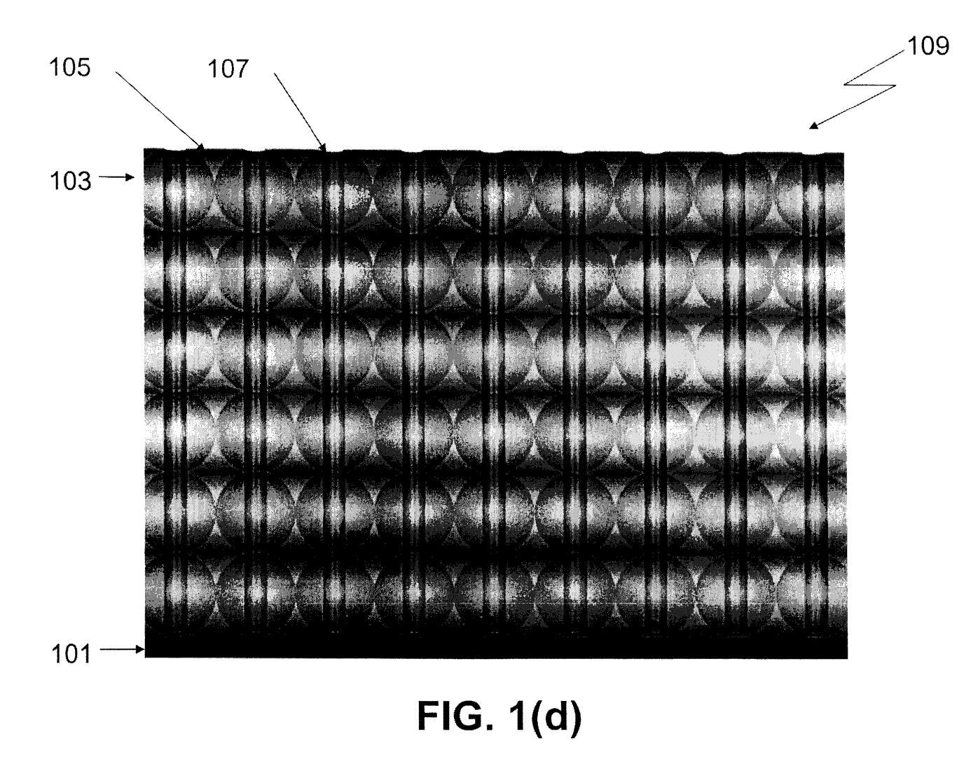

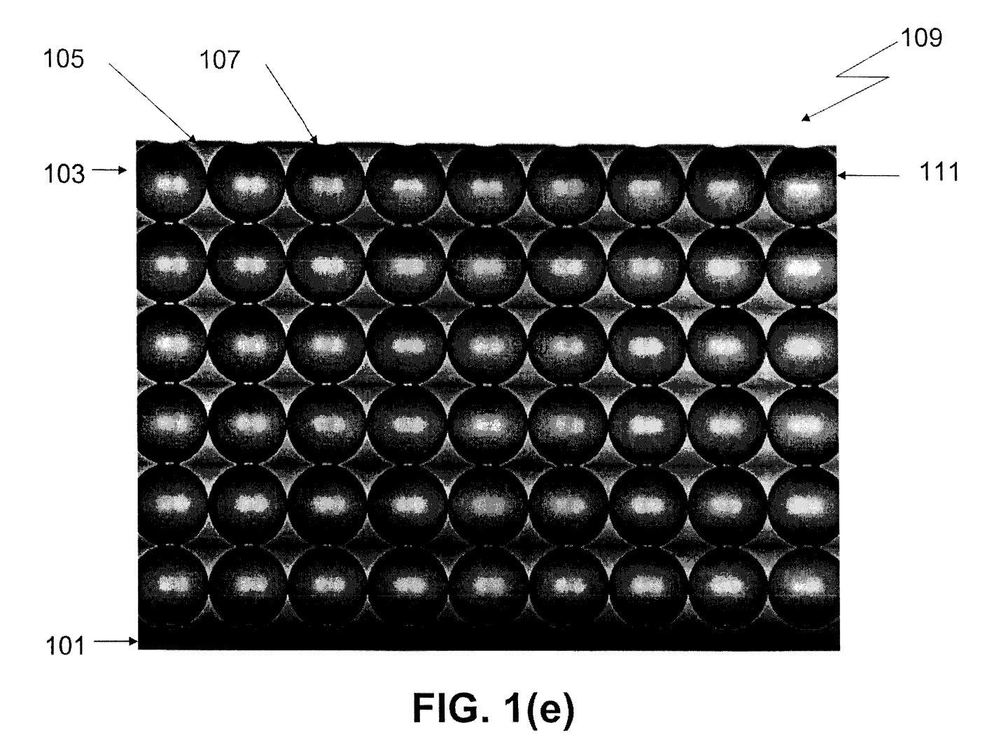

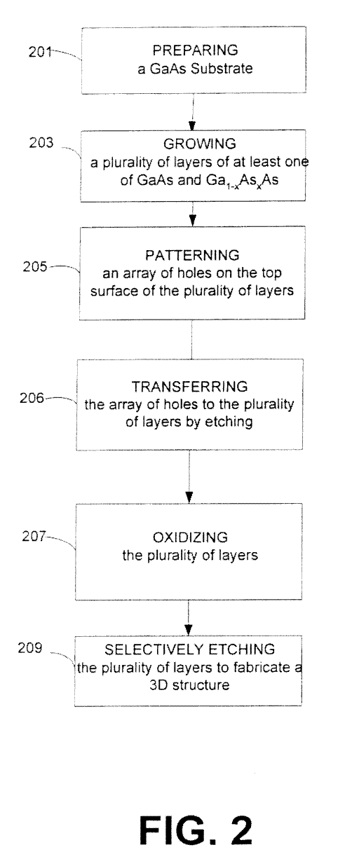

The exemplary FIG. 1(a) to FIG. 1(e) illustrate the steps in method of the present invention. FIG. 2 is an exemplary flow diagram of the steps of the method shown in FIG. 1.

In particular, FIG. 1(a) illustrates a GaAs substrate 101. Preferably, preparing the GaAs substrate 101 at least comprises the removal of surface contaminants and native oxide. In addition, removing the surface contaminants and native oxide is preferably performed by using at least one of organic and inorganic solvents. Preparing the GaAs substrate is shown as process step 201 in FIG. 2.

FIG. 1(b) discloses growing a plurality of layers 103 of AlₓGa₁₋ₓAs on top of the GaAs substrate 101. The concentration of A1, or the value of x, may be varied gradually as the pluralities of layers 103 are grown. Preferably, the value of x varies over the range of 0.9 to 1.0 where subsequent oxidation is desired, and less than 0.85 otherwise. Thus, the variable concentration in the plurality of layers 103 on top of the GaAs substrate 101 is not necessarily a step-wise function of the distance from the top surface 105 of the plurality of layers 103 or the top surface 102 of the GaAs substrate 101. Growth of the plurality of layers on top of the GaAs substrate is shown as method step 203 in FIG. 2.

FIG. 1(c) shows patterning an array 109 of circular openings on the top surface 105 of the plurality of layers 103. Further, FIG. 1(c) shows that the array pattern is then transferred to the underlying plurality of layers 103 by etching using an etching system. As a non-limiting example, etching can be performed by a chlorine-based dry etch using an inductively coupled plasma (ICP) etching system or focused ion beam. As a result of the etching, an array of cylindrical voids 107 is cut through the plurality of layers 103 of GaAs/AlGaAs, as shown in FIG. 1(c). Patterning the top surface of the plurality of layers 103 with an array of holes and transferring the array of holes by etching to the plurality of layers 103 is shown as process step 205 and step 206, respectively, in FIG. 2.

FIG. 1(d) shows the plurality of layers 103 grown on top of the GaAs substrate 101 being oxidized. The oxidation occurs at several hundred degrees Celsius, typically in the range between 300° C. and 600° C. in the atmosphere of water vapor and nitrogen. In particular, the oxidation rate is a function of the A1 concentration in the A1ₓGa₁₋ₓAs. The higher the A1 concentration, the faster the oxidation. As discussed above, the Al concentration may vary with the distance from the top surface of the plurality of layers 103 grown on top of the GaAs substrate 101. Thus, the oxidation that starts at the inner surface of the cylindrical openings may proceed sideways at rates that are a function of the distance from the top surface 105 of the plurality of layers 103 or the top of the GaAs substrate 101.

As shown in FIG. 1(d), due to the variations in the oxidation rate discussed above, it is possible to engineer the profile of Al concentration such that the resulting oxidized regions are spherical, spheroidal, or of another shape that is desirable in a three-dimensional structure to be fabricated. Oxidation of the plurality of layers 103 grown on top of the GaAs substrate 101 is shown as step 207 of the method in FIG. 2.

FIG. 1(e) shows the plurality of layers 103 grown on top of GaAs substrate 101 being subjected to selective oxide etching. Preferably, the selective etching is performed with an aqueous solution of hydrofluoric acid (HF). In particular, HF selectively attacks the oxidized regions of the plurality of layers 103 while leaving un-oxidized regions intact. As a result, voids 111 are opened where the region was oxidized, and the structure shown in FIG. 1(e) results. Selective etching of the plurality of layers 103 grown on top of the GaAs substrate 101 is shown as process step 209 of the process in FIG. 2. From the above description of the process of the present invention, it should be clear that the particular materials (GaAs/AlGaAs, HF, Cl-based dry etch, water-vapor-based oxidation) can be replaced with other compounds and procedures such as Si/SiOₓ material system, fluorine-based dry etch, and hydrofluoric wet etch without departing from the spirit of the invention.

The resulting symmetry of the structure depends on the symmetry of the patterned array of holes shown in FIG. 1(c) and indicated in process step 205 of FIG. 2. For example, if a square array of circular holes is patterned with the lattice constant equal to the vertical period of the stack, a cubic three-dimensional array of voids can be created.

The advantage of the method of the present invention lies mainly in its simplicity. Namely, a fully three-dimensional structure can be created using a purely two-dimensional patterning of the top surface of a plurality of layers grown on top of the GaAs substrate. In contrast, to background art methods, the proposed process requires no alignment since a single lithography step is used to create the entire volume of the three-dimensional photonic crystal.

Using the method of the present invention described above, it is easy to incorporate active photonic structures such as quantum wells for the creation of laser sources embedded in the photonic crystal. In this case, the growth of GaAs/AlGaAs is simply modified to include a stack of quantum wells. Such active devices, which are embedded in 3D photonic crystals, can be pumped either optically or electrically. The latter option is allowed by the preservation of electrical path between the top surface and the substrate. At the same time, optical isolation of the top electrical contact from the active layer is provide by several periods of photonic crystal.

The simplicity of the process of the present invention allows contemplating uses of photonic crystals that hitherto have been impractical or difficult/impossible to realize. One example is the realization of a low-threshold or threshold-less laser. Such a device, which has been described and analyzed theoretically in the literature (e.g., K. Aoki, H. Hirayama, Y. Aoyagi, RIKEN Review No. 33, (2001)) would consist of an emitter buried in a three-dimensional photonic crystal that exhibits a full 3D photonic bandgap, and is feasible using the disclosed process. In addition, a variety of passive photonic-crystal-based structures can be realized, many of which have been described in the literature.

It should be noted that available photonic crystal lattice geometries are limited to those that can be decomposed into layers with vertical holes penetrating all the layers. This limits the types of defects that can be engineered in the photonic crystal structure to:

(1) planar-horizontal (e.g., one layer of the stack would have a specific Al profile);

(2) planar-vertical (e.g., a row of patterned holes would differ from the rest of the lattice); and

(3) linear-vertical (e.g., one patterned hole would be different), and

(4) intersection of vertical and horizontal defects listed above.

However, it is not clear how important these restrictions are to the functionality of the obtainable three-dimensional structures.

A way to overcome these limitations consists of making two separate photonic crystals using the method of the present invention technique and sandwiching an arbitrary structure between them using, for example, wafer fusion. Such a process would be more complicated, as it would require two alignment steps and two wafer fusions. However, this approach is still considerably simpler than building the entire 3D photonic crystal in a layer-by-layer fashion as investigated by other researchers.

1. A method for fabricating three-dimensional structures comprising:
preparing a GaAs substrate;
growing a plurality of layers on top of the GaAs substrate;
patterning the top surface of the plurality of layers with an array of holes;
transferring the array of holes to the plurality of layers by etching;
oxidizing the plurality of layers to fabricate three-dimensional structures,
wherein preparing a GaAs substrate further comprises removing surface contaminants and native oxide from the GaAs substrate.

2. The method of claim 1, wherein the oxidized regions are selectively etched.

3. The method of claim 2, wherein removing surface contaminants and native oxide is performed by using at least one of organic and inorganic solvents.

4. The method of claim 1, wherein the plurality of layers further comprises layers of Ga₁₋ₓA1ₓAs, wherein at least two of the plurality of layers differ in A1 content.

5. The method of claim 4, wherein a concentration of Al and Ga are varied in accordance with a value for x.

6. The method of claim 5, wherein transferring the array of holes further comprises using a chlorine-based dry etch.

7. The method of claim 6, wherein oxidizing the plurality of layers is performed in a temperature range of 300° C. and 600° C.

8. The method of claim 7, wherein oxidizing the plurality of layers is performed in an atmosphere containing water.

9. The method of claim 8, wherein oxidizing the plurality of layers is performed in an atmosphere of water vapor and nitrogen.

10. The method of claim 9, wherein selective etching of the oxidized plurality of layers is performed by using an aqueous solution of hydrofluoric acid.

11. A method for fabricating three-dimensional structures comprising:
preparing a substrate;
growing a plurality of layers on top of said substrate where at least two of the plurality of layers differ in chemical composition;
patterning the top surface of the plurality of layers with a plurality of holes;
transferring the plurality of holes to the plurality of layers by etching;
exposing the plurality of layers to a fluid chemical agent where a reaction rate of a fluid chemical agent is dependent on a chemical composition of the plurality of layers;
thereby creating a three-dimensional structure of varied chemical composition.

12. The method of claim 11, wherein said plurality of layers comprises at least one layer of Ga₁₋ₓA1ₓAs.

13. The method of claim 12, wherein the fluid chemical agent comprises water vapor to oxidize Ga₁₋ₓA1ₓAs.

14. The method of claim 13, wherein said oxidized Ga₁₋ₓA1ₓAs is subsequently selectively removed.

15. The method of claim 14, wherein an aqueous solution of hydrofluoric acid is used to remove said oxidized Ga₁₋ₓA1ₓAs.
